(19) United States
(12) Patent Application Publication
(10) Pub. No.: US 2008/0261382 A1
(43) Pub. Date: Oct. 23, 2008

(54) WAFER DICING USING A FIBER MOPA

(76) Inventors: Andrei STARODOUMOV, Cupertino, CA (US); Norman Hodgson, Belmont, CA (US); Terry Hannon, Morgan Hills, CA (US)

Correspondence Address: STALLMAN & POLLOCK LLP, 353 SACRAMENTO STREET, SUITE 2200, SAN FRANCISCO, CA, 94111, US

(21) Appl. No.: 12/045,519

(22) Filed: Mar. 10, 2008

Related U.S. Application Data
(60) Provisional application No. 60/925,219, filed on Apr. 19, 2007.

(51) Int. Cl. H01L 21/02; B23K 26/16

(52) U.S. Cl. 438/463; 219/121.67; 257/E21.002

(57) ABSTRACT

Silicon wafer dicing apparatus includes a master oscillator power amplifier (MOPA) arrangement wherein the master oscillator includes a continuous wave (CW) laser the output of which modulated by an external modulator to provide optical pulses to be amplified in the power amplifier. In one example of the apparatus the power amplifier includes at least one amplification stage including an optical fiber gain-medium.

### PRIORITY CLAIM

This application claims the priority of provisional patent application Ser. No. 60/925,219 filed Apr. 19, 2007, the complete disclosure of which is hereby incorporated by reference.

### TECHNICAL FIELD OF THE INVENTION

The present invention relates in general to dicing semiconductor wafers during semiconductor manufacturing to divide the wafers into individual chips or dice. The invention relates in particular to dicing such wafers using a scanned beam from a pulsed laser.

### DISCUSSION OF BACKGROUND ART

Wafer dicing is an operation used in the manufacture of semiconductor devices to separate a processed, silicon semiconductor wafer into individual dice, usually referred to as semiconductor “chips”. At present, most wafer dicing is done using a mechanical saw or a mechanical scribe. There is, however, a growing interest in performing dicing operations using a scanned beam from a pulsed laser. Pulsed lasers delivering radiation in the near-infrared (NIR) region of the electromagnetic spectrum and in the ultraviolet (UV) region of the electromagnetic spectrum have been investigated. Typically the IR radiation is provided by lasers using a gain-medium of neodymium-doped YAG (Nd:YAG) or neodymium-doped yttrium vanadate (Nd:YVO₄) each of which is used to generate radiation having a wavelength of about 1064 nanometers (nm). UV radiation is usually provided by converting the fundamental radiation of such lasers into radiation having the third-harmonic wavelength of the fundamental radiation, for example, about 355 nm for 1064 nm fundamental radiation.

Silicon wafers have a high absorption coefficient in the UV and visible regions of the electromagnetic spectrum and are semi-transparent at wavelengths of about 1064 nm. A beam of pulsed UV radiation provides a smooth, high-quality cut but requires a relatively high peak pulse-power. This is more difficult to obtain in UV than in NIR spectral range because of a relatively low efficiency of frequency (wavelength) conversion. NIR radiation penetrates deeper into a wafer than UV radiation. This can cause thermal stresses and potential breakage of a wafer. This problem has been overcome by using relatively short pulses, for example pulses having a duration between about 1 nanosecond (ns) and 10 ns. Such short pulses can generate a plasma when focused on a wafer surface. The plasma absorbs the IR radiation, providing heat for the dicing process while avoiding thermal damage to the wafer.

It is usually desirable in semiconductor device manufacturing to have the highest possible device throughput for minimizing production cost. One way to increase throughput is to increase wafer-dicing speed. In laser dicing of wafers, cuts are made by scanning a pulsed laser beam along a line such that individual pulses overlap on the wafer. Cutting speed accordingly is dependent inter-alia on the peak power and pulse-repetition rate (PRF) in the laser beam.

Commercially available pulsed lasers than can be used for wafer dicing are typically actively Q-switched lasers. In such lasers, an electro-optical switch is used to periodically inhibit laser action in a laser resonator until energy in the gain-medium, creating by optically pumping the gain-medium, has built up to a desired level, and then is switched to allow laser action in the resonator creating a higher power, short optical output pulse. A typical PRF for such actively Q-switched pulsed lasers is about 25 kilohertz (kHz). Developmental and state-of the art actively Q-switched lasers having a PRF up to about 250 kHz have been reported. Problems encountered when operating Q-switched solid-state lasers at a PRF in excess of about 100 kHz include pulse instabilities and pulses having a longer than desirable pulse-duration, for example, about 30 ns or greater. A Q-switched, cavity-dumped, pulsed solid-state NIR laser operating at a PRF of about 100 kHz with pulses having a duration of about 1 ns is described in U.S. Pat. No. 5,870,421. This performance, however was obtained at the cost of using a complicated optical scheme and an expensive high voltage intracavity electro-optical modulator (Q-switch) for cavity-dumping to generate the short pulses.

If laser dicing of wafers is to be widely commercially practiced there is a need for a relatively simple, stable pulsed laser system having a pulse repetition rate preferably in excess of about 100 kHz. The pulses from such a laser should preferably have a duration less than about 30 ns, a peak power preferably greater than less 1 kilowatt (KW) and a wavelength in the in IR, visible, or UV ranges of the electromagnetic spectrum.

### SUMMARY OF THE INVENTION

The present invention is directed to apparatus for dicing a semiconductor wafer. In one aspect apparatus in accordance with the present invention comprises a master oscillator arrangement for providing a sequence of optical pulses at a predetermined pulse-repetition frequency (PRF), an optical amplifier arrangement including at least one amplification stage arranged to amplify optical pulses in the sequence thereof to provide a dicing beam including a sequence of amplified optical pulses. An arrangement is provided for directing the dicing beam onto the semiconductor wafer and effecting relative motion between the dicing beam and the semiconductor wafer. The master oscillator arrangement includes one of a directly modulated semiconductor laser and a continuous wave (CW) laser, the output of each of which is modulated by an external modulator.

Embodiments of the invention can be operated at a PRF of about 100 kHz or greater, with pulse-durations less than about 30 ns. In a particular example, the PRF is between about 300 kHz and 500 kHz with pulse-durations between about 1 ns and 15 ns. The use of an externally modulated master oscillator provides flexibility is selecting an optimum pulse-duration for a particular arrangement.

### BRIEF DESCRIPTION OF THE DRAWINGS

FIG. 1 schematically illustrates one embodiment of apparatus in accordance with the present invention including a pulsed fiber MOPA arrangement, a scanner head (galvanometer system) for delivering an optical beam from the MOPA to a wafer, and a wafer holder for holding and positioning a wafer with respect to the optical beam.

FIG. 2 schematically illustrates one example of a pulsed fiber MOPA arrangement suitable for use as the MOPA arrangement of FIG. 1.

FIG. 3 schematically illustrates another embodiment of apparatus in accordance with the present invention, similar to the apparatus of FIG. 1 but further including a harmonic-generation stage for tripling the frequency of radiation from the fiber MOPA such that the beam delivered to the wafer has a wavelength one-third of the wavelength delivered from the fiber MOPA.

FIG. 4 schematically illustrates yet another embodiment of apparatus in accordance with the present invention, similar to the apparatus of FIG. 3 but further including bulk amplifier stage located between the fiber MOPA and the harmonic-generation stage.

### DETAILED DESCRIPTION OF THE INVENTION

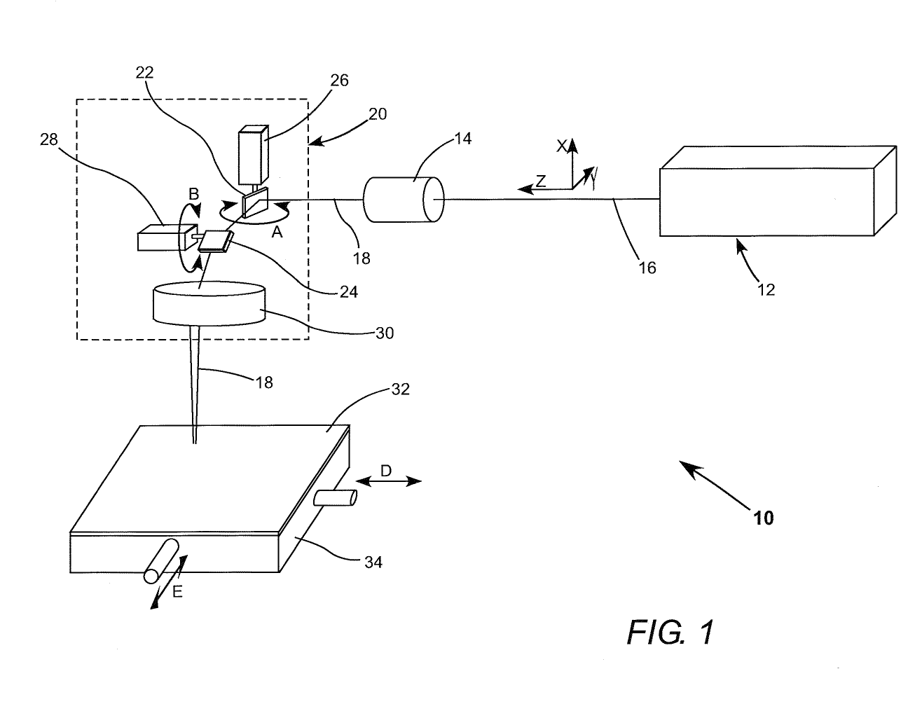

Turning now to the drawings, wherein like features are designated by like reference numerals, FIG. 1 schematically illustrates one preferred embodiment 10 of apparatus in accordance with the present invention for wafer dicing. Apparatus 10 includes a pulsed fiber MOPA arrangement 12 and a beam-shaping arrangement 14 for shaping an output beam 16 from the fiber MOPA. A shaped beam 18 is delivered to a scanner head (galvanometer system) 20. Scanner head 20 includes two mirrors 22 and 24 driven by motors 26 and 28, respectively. Mirror 22 scans the beam in an X-axis thereof as indicated by arrow A. Mirror 24 scans the beam in a Y-axis thereof as indicated by arrow B. The beam propagates along a Z-axis. The X-, Y-, and Z-axes are mutually perpendicular. The scanned beam is delivered to aberration corrected optics 30, such as an F-theta lens, arranged to focus the beam on a wafer 32 to be diced. Wafer 32 is preferably mounted on an X-Y translation stage 34 for holding the wafer and positioning a wafer with respect to the focused beam as indicated by arrows D and E.

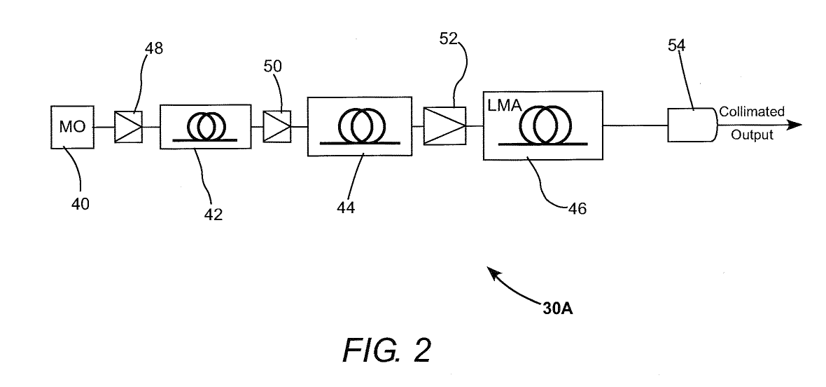

FIG. 2 schematically illustrates one preferred example 30A of a fiber MOPA arrangement suitable for use as fiber MOPA 12 in apparatus 10. MOPA 30A includes a narrow-linewidth master oscillator preferably having a linewidth less than 1.0 nanometers (nm) measured at about 20 dB level from the peak of the line spectrum. Master oscillator (MO) 40 is preferably modulated at high pulse-repetition frequency (PRF), for example between about 100.0 kilohertz (kHZ) and 10.0 megahertz (MHz). Master oscillator 40 preferably delivers pulses having a duration between about 0.1 nanoseconds (ns) and about 15.0 ns. These pulses serve as seed signals for a sequence (cascade) of two fiber pre-amplifiers 42 and 44 and a large mode area (LMA) fiber amplifier 46. These three fiber amplifiers (three stages of fiber amplification) can be regarded for practical purposes as the power amplifier (PA) of MOPA 12. The MO and the three fiber amplifiers are connected with each other via isolation devices 48, 50, and 52. A fiber collimator 54 provides collimated output of the MOPA. Any of the isolation devices may be a pass-band spectral filter, an acousto-optical modulator, or a directional isolator. A purpose of the isolation devices is to suppress back and forth propagating amplified spontaneous emission and back reflected signal and prevent self-excitation in cascaded amplifiers. The LMA fiber-amplifier suppresses nonlinear optical effects such as stimulated Raman scattering and stimulated Brillouin scattering.

The above discussed fiber MOPA arrangement using a modulated seed-source provides higher processing speed operation with pulse repetition frequencies compared with electro-optically (E-O) Q-switched solid-state lasers. The all-fiber arrangement simplifies design of the apparatus, reduces alignment procedures and reduces cost of the system by avoiding a need for a high speed and high voltage electro-optic Q-switch device in a solid-state laser resonator (cavity).

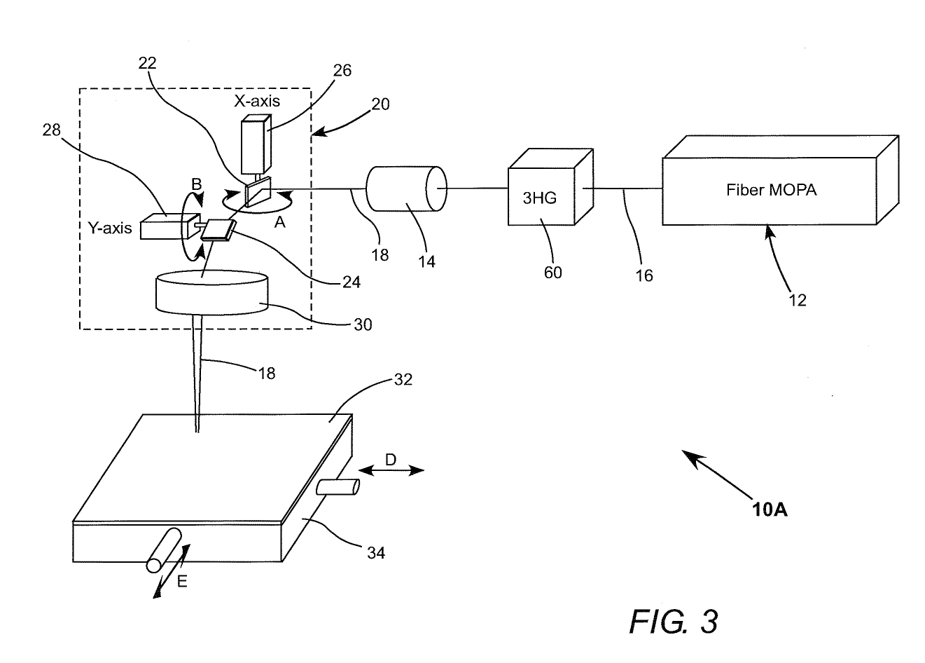

FIG. 3 schematically illustrates another preferred embodiment 10A of wafer-dicing apparatus in accordance with the present invention. Apparatus 10A is similar to apparatus 10 of FIG. 1 with an exception that a third-harmonic generating (3HG) stage 60 is located between fiber MOPA 12 and beam shaping optics 14. 3HG stage 60 includes two optically nonlinear crystals (not shown) arranged to triple the frequency of radiation in beam 16 delivered from the fiber MOPA, accordingly radiation in beam 17 delivered from the 3HG stage has a wavelength that is one-third the wavelength of radiation in beam 16. By selecting a fundamental wavelength of the fiber MOPA in the near infrared (NIR) spectral region, for example between about 1030 nm and about 1060 nm, the wavelength of radiation in beam 17 can be in the ultraviolet (UV) spectral region, correspondingly having a wavelength between about 343 nm and about 360 nm. UV radiation is strongly absorbed by silicon wafer material and can provide a better cut-quality than NIR radiation.

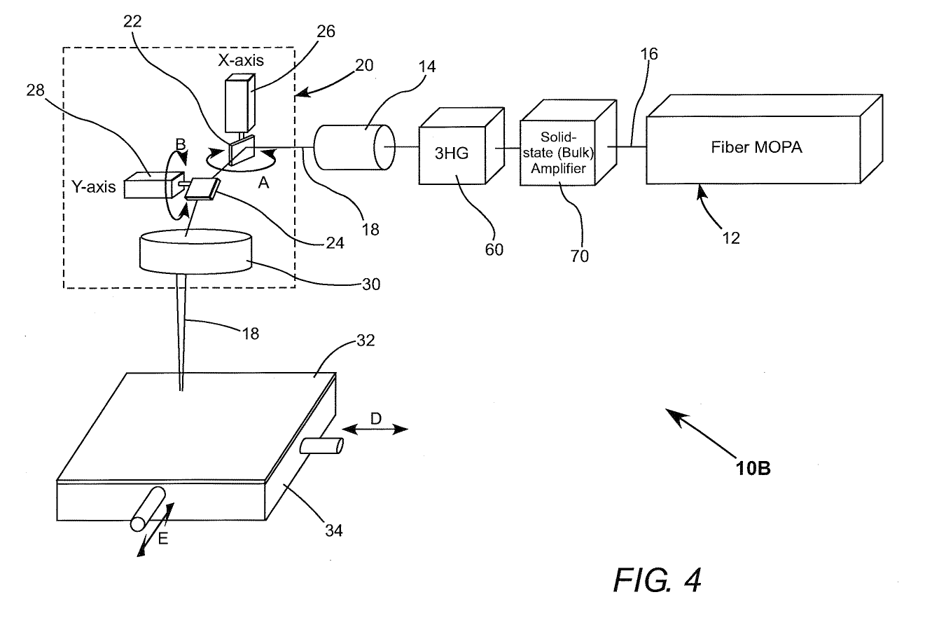

FIG. 4 schematically illustrates yet another preferred embodiment 10B of wafer dicing apparatus in accordance with the present invention. Apparatus 10B is similar to apparatus 10A of FIG. 3 with an exception that a solid-state (bulk) amplifier stage 70 is included between fiber MOPA 12 and third-harmonic generating stage 60. Preferably the average output power of the fiber MOPA is limited to between about 20.0 W and 40 W average, with amplification to between about 40 W and 80 W or in the solid-state amplification stage. This would provide between about 10 W and 20 W of UV average power from the third-harmonic generation stage.

A purpose of solid-state amplifier 70 is to increase the NIR power delivered by fiber MOPA 30 while keeping the spectral linewidth of the amplified NIR radiation narrow enough for efficient frequency-conversion. The solid-state amplification stage is preferred over another fiber-amplifier stage because in a fiber amplifier, nonlinear optical effects such as stimulated Raman scattering (SRS), stimulated Brillouin scattering (SBS), and spectral broadening due to four-wave mixing eventually limit peak pulse-power that can be obtained from a fiber MOPA. Efficiency of the frequency-conversion process in 3HG-stage 60 grows with peak pulse power in the NIR range spectral region. A solid-state amplifier with a large beam cross-section (typically ˜1 mm compared to between about 10.0 micrometers (mm) and about 50.0 in amplifier fibers) in the amplifier gain-element provides little nonlinear effects in the gain-element and increase a peak-power beyond a fiber MOPA limit. Accordingly higher peak and average powers in the UV spectral region are available in apparatus 10B than in apparatus 10A. A suitable solid state amplifier could be based on either an Nd:YAG or Vandadate gain medium.

Referring again to FIG. 2, master oscillator 40 can be a externally-modulated solid-state laser, fiber laser or semiconductor laser that provides radiation with required parameters such as spectral width, pulse repetition rate, and pulse duration. Q-switched solid-state lasers and fiber lasers are not very attractive as master oscillators for systems with a high pulse repetition rate (>100 kHz) or where variable repetition rate with a fixed pulse duration is required, since it is very difficult to get a short pulse length (<15 ns) at high pulse repetition rate.

One option for generating a short optical seed-pulses is to use a continuously operating (cw) optical source modulated by an external modulator. In such a system, a seed source, such as a diode-laser or a fiber laser, which is a single-frequency source operating in one longitudinal mode with a narrow linewidth of 1 kHz-50 MHz, is modulated with an external modulator providing pulses having a duration between about 0.1 ns-15 ns. A modulator, for a diode-laser or a fiber laser is preferably an electro-optical crystal in a waveguide Mach-Zehnder configuration. This type of modulator requires much less voltage (˜5 Volts) than bulk a electro-optical modulator (>100 Volts) used in solid-state laser cavities and is less expensive than a bulk modulator.

A second option for generating a short optical seed-pulses is to use a directly modulated diode-laser as a seed source. Such an approach is, in general, less expensive, and provides higher peak power (above 1 W) from the seed laser compared to modulated cw light (peak power is less than 300 mW using a waveguide LiNbO3 modulator).

A detailed description for both an externally modulated and a directly modulated diode-laser is provided in U.S. Pre-Grant Publication No. 2006/0222372, the complete disclosure of which is hereby incorporated by reference.

Directly modulating a diode laser has the advantage of independent control of pulse length and pulse repetition rate. Preferably a narrow line DBR laser (Distributed Bragg Reflector) or DFB (Distributed Feedback) laser are used as a seed source. Such lasers have a short cavity length (<5 mm) that provides a fast response time to applied electrical pulses, for example pulses having a pulse duration less than 100 picoseconds (ps).

A new type of diode-laser, referred to as a long-cavity diode-laser, has recently been developed In contrast to DFB and DBR diode-lasers, a long-cavity diode-laser has its output mirror placed not on a diode chip, but out of the chip, namely, in a fiber pigtail or waveguide optically coupled to a diode-laser in a chip. A fiber Bragg grating (FBG) written into the fiber pigtail functions as an output coupler. This provides for operation of the diode-laser in either in a single-longitudinal mode (linewidth about 50 MHz or less) or many longitudinal modes (linewidth between about 10 and 100 gigahertz). With overall cavity length of less than about 8 mm, such a laser exhibits fast response time, for example less than about 1 ns, to external modulation. That response is fast enough to generate pulses of having a pulse-duration between about 1 and about 15 ns. Long cavity diode-lasers are available from Lumics GmbH of Berlin, Germany.

It should be noted here that in apparatus 10, wherein NIR radiation is used directly for wafer dicing, the linewidth of the fiber MOPA output does not play an important role in the dicing process. Narrow linewidth, for example less than about 1 nm, linearly polarized and high peak power (>2 kW) is required in apparatus 10A and in apparatus 10B for efficient conversion of IR light into visible and UV range. Additionally, the signal from a master oscillator must have a higher spectral contrast ratio, for example greater than about 20 dB, between spectral amplitude at the peak of the spectrum and the spectral amplitude at wings of the spectrum. This helps to reduce pulse spectral broadening due to four-wave mixing.

In apparatus wherein fiber MOPA 12 has a diode-laser master oscillator, the output peak power of the diode-laser, typically between about 0.1 W and about 1 W, has to be amplified to multi-kilowatt level in a multi-stage fiber amplifier as described above. Taking into account that the pulse spectrum does suffer some broadening due to effects discussed above, a single-frequency (single longitudinal mode) master oscillator is preferable in a MOPA 30 in apparatus 10A and apparatus 10B.

The present invention is described above in terms of a preferred and other embodiments. The invention is not limited, however, to the embodiments described and depicted. Rather, the invention is limited only by the claims appended hereto.

What is claimed is:

1. Apparatus for dicing a semiconductor wafer, comprising:
a master oscillator arrangement for providing a sequence of optical pulses at a predetermined pulse-repetition frequency (PRF);
an optical amplifier arrangement including at least one amplification stage arranged to amplify optical pulses in the sequence thereof to provide a dicing beam including a sequence of amplified optical pulses;
an arrangement for directing the dicing beam onto the semiconductor wafer, while permitting relative motion between the dicing beam and the semiconductor wafer; and
wherein the master oscillator arrangement includes one of a directly modulated semiconductor laser and a continuous wave (CW) laser the output of which is modulated by an external modulator.

2. The apparatus of claim 1, wherein one of the optical amplifier arrangement and the master oscillator arrangement includes an optical fiber gain-medium.

3. The apparatus of claim 1, wherein the master oscillator arrangement includes an externally modulated CW semiconductor.

4. The apparatus of claim 1, wherein the master oscillator is modulated at a pulse-repetition frequency (PRF) between about 100.0 kilohertz and 10.0 megahertz.

5. The apparatus of claim 4, wherein the pulses provided by the master oscillator having a duration between about 0.1 nanoseconds and about 15 nanoseconds.

6. The apparatus of claim 1, wherein the amplified pulses delivered by the optical amplifier have a wavelength between about 1030 nanometers and about 1060 nanometers, and the apparatus further includes a harmonic-generator arranged to reduce the wavelength of the amplified pulses to between about 343 nanometers and about 360 nanometers before the dicing beam is directed onto the semiconductor wafer.

7. The apparatus of claim 6, wherein the optical amplifier includes a sequence of three fiber-amplifier stages.

8. The apparatus of claim 7, wherein the optical amplifier further includes a bulk optical amplification stage between the fiber-amplifier stages and the harmonic-generator.

9. Apparatus for dicing a semiconductor wafer, comprising:
a master oscillator arrangement for providing a sequence of optical pulses at a predetermined pulse-repetition frequency (PRF), the pulses having a wavelength between about 1030 nanometers and about 1060 nanometers;
an optical amplifier arrangement including at least one fiber amplification stage arranged to amplify optical pulses in the sequence thereof to provide a sequence of amplified optical pulses;
a harmonic-generator arranged to reduce the wavelength of the amplified pulses to an ultraviolet (UV) wavelength between about 343 nanometers and about 360 nanometers thereby providing a dicing beam including a sequence of UV-wavelength optical pulses;
an arrangement for directing the dicing beam onto the semiconductor wafer, while permitting relative motion between the dicing beam and the semiconductor wafer; and
wherein the master oscillator arrangement includes one of a directly modulated semiconductor laser and a continuous wave (CW) laser the output of which is modulated by an external modulator.

10. The apparatus of claim 9, wherein the master oscillator is modulated at a pulse-repetition frequency (PRF) between about 100.0 kilohertz and 10.0 megahertz.

11. The apparatus of claim 10, wherein the pulses provided by the master oscillator having a duration between about 0.1 nanoseconds and about 15 nanoseconds.

12. The apparatus of claim 9, wherein the optical amplifier includes first, second, and third amplification stages numbered in sequence of increasing power output.

13. The apparatus of claim 12, wherein the optical amplifier further includes a bulk optical amplification stage between the third fiber-amplifier stage and the harmonic generator.

14. A method for dicing a semiconductor wafer comprising the steps of:
generating a pulsed laser output beam having a pulse repetition frequency of at least 100.0 kilohertz using an externally modulated CW diode laser;
amplifying the pulses using a multi-stage fiber amplifier;
converting the frequency of the pulses to a wavelength in the UV spectrum; and
scanning the pulsed output beam over the wafer to cut the wafer into separate die.

15. A method as recited in claim 14, further including the step of using a solid state amplifier to amplify the previously amplified pulses prior to the frequency conversion step.

16. A method as recited in claim 14, wherein the width of the pulses is between 0.1 nanoseconds and 15.0 nanoseconds.
